(19) United States
(12) Patent Application Publication
(10) Pub. No.: US 2007/0132512 A1
(43) Pub. Date: Jun. 14, 2007

(54) Variable gain amplifier

(75) Inventors: Takahito Miyazaki, Osaka (JP); Iwao Kojima, Kyoto (JP)

Correspondence Address: STEVENS, DAVIS, MILLER & MOSHER, LLP, 1615 L. STREET N.W., SUITE 850, WASHINGTON, DC, 20036, US

(73) Assignee: MATSUSHITA ELECTRIC INDUSTRIAL CO., LTD., Osaka (JP)

(21) Appl. No.: 11/604,829

(22) Filed: Nov. 28, 2006

(30) Foreign Application Priority Data
Nov. 30, 2005 (JP) 2005-346282

(51) Int. Cl. H03G 3/00

(52) U.S. Cl. 330/278

(57) ABSTRACT

A variable gain amplifier is provided that scarcely suffers disturbance or interference such as carrier leak from other circuit blocks even when a plurality of circuits are constructed on the same semiconductor substrate, and that has low output impedance fluctuation. For the purpose of this, in a variable gain amplifier, the ground terminal of a signal amplifying transistor is connected to a dedicated grounding pad to which the other circuit blocks are not connected, so that disturbance or interference such as carrier leak from other circuit blocks is reduced. Further, the ground terminal of an output impedance compensation circuit is also connected to the same grounding pad described above, so that further disturbance or interference is avoided. As a result, the circuit scarcely suffers disturbance or interference such as carrier leak from other circuit blocks, so that output impedance fluctuation is reduced.

### BACKGROUND OF THE INVENTION

1. Field of the Invention

The present invention relates to a variable gain amplifier and a wireless circuit system employing the same. In particular, the variable gain amplifier of the present invention is used for amplifying a high frequency signal in wireless communication devices of various kinds, where output characteristics is improved and disturbance or interference such as carrier leak from other circuit blocks is reduced.

2. Prior Art

In recent years, development of integrated circuits employing bipolar transistors or field effect transistors is progressing for the application of high frequency circuits for telecommunication. An example of such integrated circuit blocks is an amplifying circuit that requires gain control.

FIG. 6 is a circuit diagram showing the configuration of a prior art variable gain amplifier employing a field effect transistor. As shown in FIG. 6, in the prior art variable gain amplifier, a high frequency signal inputted through an input terminal IN is amplified by a signal amplifying field effect transistor 201, and then outputted through an output terminal OUT. At that time, the gain of the signal amplifying field effect transistor 201 can be controlled with a gain control signal inputted through a gain control terminal 211. Between the gain control terminal 211 and the gate of the signal amplifying field effect transistor 201, a bias supplying resistor 206 is provided.

Further, in this variable gain amplifier, an output impedance compensation circuit 216 is added to the drain serving as the output terminal of the signal amplifying field effect transistor 201. The output impedance compensation circuit 216 comprises an output impedance compensating field effect transistor 202, resistors 203a, 203b, and 203c, and capacitors 204a and 204b, and compensates fluctuation of the output impedance of the signal amplifying field effect transistor 201 viewed from the output terminal (the drain) side.

In the subsequent stage of the variable gain amplifier, another circuit block such as a filter is connected in many cases. At the time, in the case of high frequency, in order that reflection and loss of the signal should be reduced, impedance matching is generally established between the circuit blocks. Thus, the output impedance of the variable gain amplifier is desired to be always constant regardless of the gain. Accordingly, in the prior art, a variable gain amplifier has been devised in which the output impedance compensating field effect transistor 202 is controlled simultaneously on the basis of a signal generated from the gain control signal, so that output impedance fluctuation is compensated, so that output impedance fluctuation is reduced (see Japanese Laid-Open Patent Publication No. H7-263968).

Nevertheless, in recent years, the size of wireless circuit systems employing a variable gain amplifier tends to increase. Thus, even variable gain amplifiers that have conventionally been fabricated on a separate semiconductor substrate tend to be fabricated on the same semiconductor substrate as that for other semiconductor circuits (circuit blocks) such as a local oscillator and a mixer. This has caused a problem that interference characteristics such as carrier leak characteristics degrades. This is because disturbance waves or interference waves leak from the local oscillator, the frequency divider, the mixer, and the like to the substrate or the supply voltage line, so that the disturbance waves or interference waves enter into the variable gain amplifier via the substrate, the supply voltage applying terminal, and the like, and are then amplified by the variable gain amplifier.

Further, when an output impedance compensation circuit for improving the output characteristics is added, interference waves or disturbance waves enter into the variable gain amplifier via the output impedance compensation circuit, so that a problem has arisen that the carrier leak characteristics degrades further.

### SUMMARY OF THE INVENTION

Thus, an object of the present invention is to provide: a variable gain amplifier that scarcely suffers disturbance or interference such as carrier leak from other circuit blocks and that has low output impedance fluctuation; and a wireless circuit system employing the same.

In order to solve the above-mentioned problems, a variable gain amplifier according to a first invention comprises: a signal amplifying element provided with a ground terminal and amplifying a high frequency signal at a gain corresponding to a gain control signal; an output impedance compensation circuit provided with a ground terminal and controlled in accordance with the gain control signal so as to compensate fluctuation of an output impedance of the signal amplifying element viewed from the output terminal side; and a grounding pad connected common to the ground terminal of the signal amplifying element and the ground terminal of the output impedance compensation circuit.

According to this configuration, since the ground terminal of the signal amplifying element and the ground terminal of the output impedance compensation circuit are connected common to the dedicated grounding pad, the amplifier scarcely suffers disturbance or interference such as carrier leak from the other circuit blocks that could be caused when the output impedance compensation circuit is provided, so that output impedance fluctuation is reduced.

A variable gain amplifier according to a second invention comprises: a signal amplifying element for amplifying a high frequency signal at a gain corresponding to a gain control signal; a load element provided with a ground terminal and connected to the signal amplifying element; an output impedance compensation circuit provided with a ground terminal and controlled in accordance with the gain control signal so as to compensate fluctuation of an output impedance of the signal amplifying element viewed from the output terminal side; and a grounding pad connected common to the ground terminal of the load element and the ground terminal of the output impedance compensation circuit.

According to this configuration, since the ground terminal of the load element and the ground terminal of the output impedance compensation circuit are connected common to the dedicated grounding pad, the amplifier scarcely suffers disturbance or interference such as carrier leak from the other circuit blocks that could be caused when the output impedance compensation circuit is provided, so that output impedance fluctuation is reduced.

This variable gain amplifier is formed together with other circuit blocks on the same semiconductor substrate in many cases.

Further, the output impedance compensation circuit has a variable resistor function of changing a resistance between the own ground terminal and output terminal, while the output terminal of the output impedance compensation circuit is connected to the output terminal of the signal amplifying element, and wherein the output impedance compensation circuit is controlled in such a manner that when the gain control signal varies in a direction of increasing the gain of the signal amplifying element, the resistance realized by the variable resistor function should increase, and that when the gain control signal varies in a direction of reducing the gain of the signal amplifying element, the resistance realized by the variable resistor function should decrease.

In the above-mentioned configuration, the variable resistor function in the output impedance compensation circuit is implemented, for example, by a bipolar transistor and a resistor, by a bipolar transistor, or alternatively by a field effect transistor.

A variable gain amplifier according to a third invention comprises: a signal amplifying element provided with a supply voltage terminal and amplifying a high frequency signal at a gain corresponding to a gain control signal; an output impedance compensation circuit provided with a supply voltage terminal and controlled in accordance with the gain control signal so as to compensate fluctuation of an output impedance of the signal amplifying element viewed from the output terminal side; and a supply voltage applying pad connected common to the supply voltage terminal of the signal amplifying element and the supply voltage terminal of the output impedance compensation circuit.

According to this configuration, since the supply voltage terminal of the signal amplifying element and the supply voltage terminal of the output impedance compensation circuit are connected common to the dedicated supply voltage applying pad, the amplifier scarcely suffers disturbance or interference such as carrier leak from the other circuit blocks that could be caused when the output impedance compensation circuit is provided, so that output impedance fluctuation is reduced.

A variable gain amplifier according to a fourth invention comprises: a signal amplifying element for amplifying a high frequency signal at a gain corresponding to a gain control signal; a load element provided with a supply voltage terminal and connected to the signal amplifying element; an output impedance compensation circuit provided with a supply voltage terminal and controlled in accordance with the gain control signal so as to compensate fluctuation of an output impedance of the signal amplifying element viewed from the output terminal side; and a supply voltage applying pad connected common to the supply voltage terminal of the load element and the supply voltage terminal of the output impedance compensation circuit.

According to this configuration, since the supply voltage terminal of the load element and the supply voltage terminal of the output impedance compensation circuit are connected common to the dedicated supply voltage applying pad, the amplifier scarcely suffers disturbance or interference such as carrier leak from the other circuit blocks that could be caused when the output impedance compensation circuit is provided, so that output impedance fluctuation is reduced.

This variable gain amplifier is formed together with other circuit blocks on the same semiconductor substrate in many cases.

Further, the output impedance compensation circuit has a variable resistor function of changing a resistance between the own supply voltage terminal and output terminal, while the output terminal of the output impedance compensation circuit is connected to the output terminal of the signal amplifying element, and wherein the output impedance compensation circuit is controlled in such a manner that when the gain control signal varies in a direction of increasing the gain of the signal amplifying element, the resistance realized by the variable resistor function should increase, and that when the gain control signal varies in a direction of reducing the gain of the signal amplifying element, the resistance realized by the variable resistor function should decrease.

In the above-mentioned configuration, the variable resistor function in the output impedance compensation circuit is implemented, for example, by a bipolar transistor and a resistor, by a bipolar transistor, or alternatively by a field effect transistor.

A wireless circuit system of the fifth invention comprises: a wireless transmission apparatus provided with at least one variable gain amplifier according to the first, the second, the third, or the fourth invention, at least one local oscillator, and at least one mixer; at least one wireless receiving apparatus; and at least one antenna connected to the wireless transmission apparatus and the wireless receiving apparatus and transmitting and receiving a radio frequency signal.

According to this configuration, the same effect is obtained as that of the first, the second, the third, or the fourth invention.

According to the variable gain amplifier and the wireless circuit system of the present invention, the circuit scarcely suffers disturbance or interference such as carrier leak from the other circuit blocks. Further, in a state that a change in the output impedance is suppressed that could be caused in association with a change in the gain, further influence of the disturbance or interference is avoided. This realizes built-in of a variable gain amplifier into a high frequency wireless circuit system, which has been difficult in the prior art because of degradation in the disturbance or interference characteristics such as carrier leak characteristics.

### BRIEF DESCRIPTION OF THE DRAWINGS

FIG. 1 is a circuit diagram showing an exemplary circuit configuration of a variable gain amplifier according to a first embodiment of the present invention and an example of other high frequency circuit blocks.

FIG. 2 is a circuit diagram showing an exemplary circuit configuration of a variable gain amplifier according to a second embodiment of the present invention and an example of other high frequency circuit blocks.

FIG. 3 is a circuit diagram showing an exemplary circuit configuration of a variable gain amplifier according to a third embodiment of the present invention and an example of other high frequency circuit blocks.

FIG. 4 is a circuit diagram showing an exemplary circuit configuration of a variable gain amplifier according to a fourth embodiment of the present invention and an example of other high frequency circuit blocks.

FIG. 5 is a block diagram showing an example of a wireless circuit system according to a fifth embodiment of the present invention.

FIG. 6 is a circuit diagram showing a prior art example of a variable gain amplifier employing an output impedance compensation circuit.

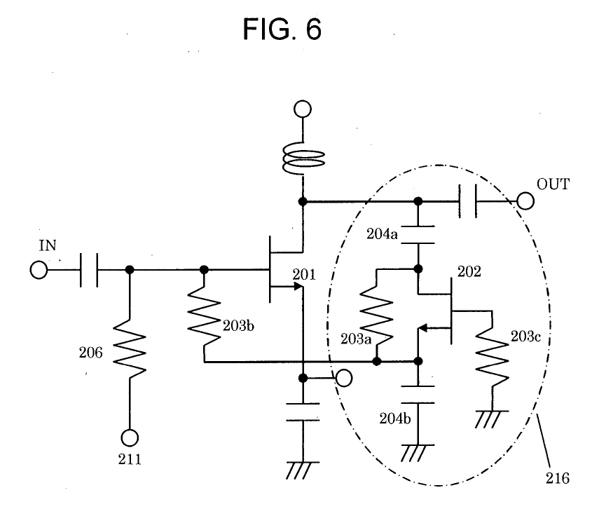

FIG. 7 is a circuit diagram showing a particular example of a control circuit.

### DESCRIPTION OF THE PREFERRED EMBODIMENTS

### First Embodiment

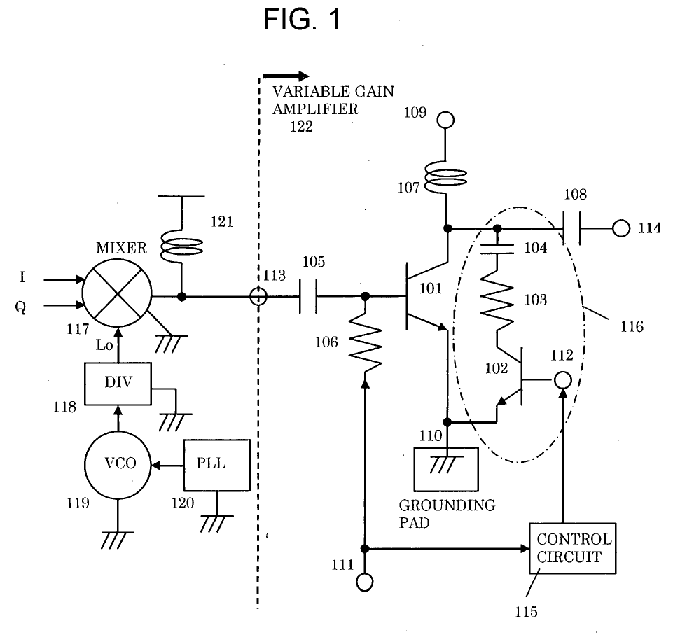

An integrated circuit according to a first embodiment of the present invention is described below with reference to FIG. 1. In the present invention, as shown in FIG. 1, a circuit apparatus is assumed in which a plurality of circuits are constructed on the same semiconductor substrate, like a wireless circuit system (block) where a mixer 117 for performing frequency conversion, a local oscillator 119, and a variable gain amplifier 122, and the like are constructed on a single chip.

In this circuit apparatus, the output signal frequency of the local oscillator 119 is controlled by a frequency synthesizer (a PLL circuit) 120. The output signal of the local oscillator 119 is divided by a frequency divider 118, so that a local oscillation signal Lo is obtained. This local oscillation signal Lo and quadrature modulation signals I and Q (baseband signals) are inputted to the mixer 117, so that an RF signal is outputted from the mixer 117. Here, the output terminal of the mixer 117 is connected through a choke coil 121 to a power supply.

The variable gain amplifier 122 of the present invention amplifies at a variable gain the RF signal outputted from the mixer 117. Specifically, in the variable gain amplifier 122, the high frequency signal inputted through an input terminal 113 is amplified by the signal amplifying transistor (a signal amplifying element) 101 and then outputted through an output terminal 114. At that time, the gain of the signal amplifying transistor 101 can be controlled with a gain control signal provided through the gain control terminal 111.

Further, in this variable gain amplifier 122, an output impedance compensation circuit (an active circuit) 116 is added to the collector serving as the output terminal of the signal amplifying transistor 101. The output impedance compensation circuit 116 comprises an output impedance compensating transistor 102, an output impedance compensating resistor 103, and a bypass capacitor 104, and compensates fluctuation of the output impedance of the signal amplifying transistor 101 viewed from the output terminal (the collector) side.

Here, the ground terminal (the emitter) of the signal amplifying transistor 101 and the ground terminal of the output impedance compensation circuit 116 are connected to a separate dedicated grounding pad 110 to which the ground terminals of the other circuit blocks are not connected.

Here, it is sufficient that the ground terminals of other circuit blocks that could cause disturbance or interference to the signal amplifying transistor 101 are solely not connected to the above-mentioned grounding pad 110. That is, one or more of the other circuit blocks that scarcely affect the characteristics of the signal amplifying transistor 101 may be connected to the grounding pad 110.

In other words, the term “dedicated” used in the present specification indicates that it is sufficient that the ground terminals of other circuit blocks that could cause disturbance or interference to the signal amplifying transistor 101 are solely not connected to the above-mentioned grounding pad 110. Thus, the ground terminals of one or more of the other circuit blocks that scarcely affect the characteristics of the signal amplifying transistor 101 may be connected to the grounding pad 110.

The circuit connection of the variable gain amplifier 122 is described below in detail.

First, the signal amplifying transistor 101 is preferably composed, for example, of an NPN type bipolar transistor. The emitter of the signal amplifying transistor 101 is connected to the dedicated grounding pad 110 to which the ground terminals of the other circuit blocks are not connected. Its base is connected through a bias applying resistor 106 to the gain control terminal 111 and further connected through an input coupling capacitor 105 to the input terminal 113 of the variable gain amplifier. Its collector is connected to a supply voltage applying terminal 109 via a load element 107 composed of a choke coil or a resistor, and further connected through an output coupling capacitor 108 to the output terminal 114 of the variable gain amplifier.

Further, the output impedance compensating transistor 102 is preferably composed, for example, of an NPN type bipolar transistor. The collector of the output impedance compensating transistor 102 is connected to the collector of the signal amplifying transistor 101 via an output impedance compensating resistor 103 and a bypass capacitor 104 or alternatively via the bypass capacitor 104 only. Its emitter is connected to the dedicated grounding pad 110. Its base 112 is connected to a control circuit 115 for the output impedance compensating transistor 102. The control circuit 115 is a circuit for generatinga control signal for the output impedance compensating transistor 102 on the basis of the gain control signal provided through the gain control terminal 111.

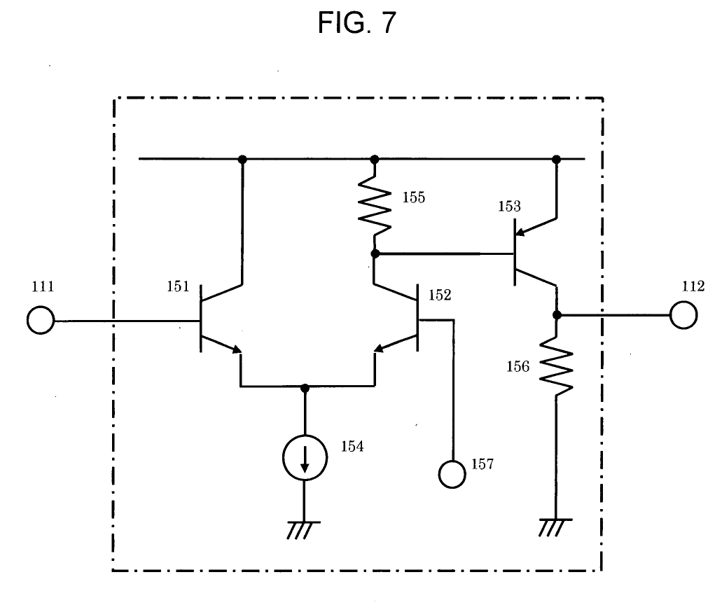

FIG. 7 is a circuit diagram showing a particular example of the control circuit 115. In FIG. 7, numerals 151 and 152 indicate NPN type transistors. Numeral 153 indicates a PNP type transistor. Numeral 154 indicates a current source. Numerals 155 and 156 indicate resistors. Numeral 157 indicates a terminal to which a constant potential is provided.

In the subsequent stage of the variable gain amplifier 122, another circuit element such as a filter is connected in many cases. At the time, in the case of high frequency, in order that reflection and loss of the signal should be reduced, impedance matching is generally established between the circuit blocks. The impedance matching indicates that components such as an inductor and a capacitance are added between the stages so that the impedance values are adjusted in such a manner that the output impedance of the preceding stage and the input impedance of the subsequent stage should be conjugate matching to each other. At the time, the output impedance of the variable gain amplifier is desired to be always constant regardless of the gain. Thus, in the present invention, the output impedance compensating transistor 102 is controlled simultaneously in response to the gain control signal provided through the gain control terminal 111 so that output impedance fluctuation is compensated. As a result, a variable gain amplifier is realized that has low output impedance fluctuation. The principles of its operation are described below.

When the gain of the signal amplifying transistor 101 is increased, the output impedance of the signal amplifying transistor 101 viewed from the collector side decreases. At that time, the output impedance compensating transistor 102 is brought into an OFF state (a high resistance state) so that the impedance viewed from the collector side is increased. As a result, the output impedance of the signal amplifying transistor 101 is mainly seen from the output terminal 114. Further, when the gain of the signal amplifying transistor 101 is reduced, the output impedance of the signal amplifying transistor 101 viewed from the collector side increases. At that time, the output impedance compensating transistor 102 is brought into an ON state (a low resistance state) so that the impedance viewed from the collector side is reduced. As a result, the impedance of the part of the output impedance compensation circuit 116 is seen from the output terminal 114.

As such, when the output impedance compensating resistor 103 and the output resistance of the output impedance compensating transistor 102 are adjusted synchronously, a variable gain amplifier is realized that has low output impedance fluctuation regardless of a change in the gain.

Here, adjustment of the resistance is described below in detail. The value of the output impedance compensating resistor 103 is adjusted in such a manner that the value of the output impedance of the signal amplifying transistor 101 viewed from the collector side should be the same when the gain of the signal amplifying transistor 101 is high (when the impedance of the signal amplifying transistor 101 is mainly seen) and when the gain of the signal amplifying transistor 101 is low (when the impedance of the output impedance compensation circuit 116 is mainly seen). During actual operation, the value of the output impedance compensating resistor 103 is fixed, while the output resistance of the output impedance compensating transistor 102 is a variable resistance.

Further, since an NPN type bipolar transistor is employed as the output impedance compensating transistor 102, in addition that ON and OFF states are realized, the impedance can be changed linearly in accordance with the change in the gain. Thus, impedance fluctuation of the signal amplifying transistor 101 can always be compensated.

On the other hand, in a circuit where a plurality of circuit blocks are constructed on the same semiconductor substrate and a plurality of ground terminals are provided, entering of interference waves or disturbance waves such as carrier leak causes a serious problem. In particular, in the case of an amplifier, the interference waves or disturbance waves having entered are amplified. Thus, care need be taken. For example, in the case of FIG. 1, the interference waves or disturbance waves indicate a signal that leaks from the frequency synthesizer 120, the local oscillator 119, the frequency divider 118, the mixer 117, the choke coil 121 or the like to the substrate or the supply voltage applying terminal, and then enters into the amplified signal of the amplifier via the substrate, the supply voltage applying terminal, or the like of the variable gain amplifier 122.

Thus, in the variable gain amplifier 122 of the present invention, the grounding pad 110 dedicated to the signal amplifying transistor 101 is provided so that disturbance or interference from the other circuit blocks is reduced.

Further, the present invention treats also the case that the above-mentioned output impedance compensation is performed in a variable gain amplifier having such a dedicated grounding pad 110.

If the ground terminal of the output impedance compensation circuit 116 were connected to a part different from the ground terminal of the signal amplifying transistor 101, interference waves or disturbance waves having entered from respective paths would go through the transistors 101 and 102, and would be added up together at the output terminal 114. As a result, if the output impedance compensation circuit 116 were connected, interference characteristics such as carrier leak characteristics would degrade.

Thus, in the present invention, the ground terminal of the output impedance compensation circuit 116 is also connected to the same grounding pad 110 as that for the signal amplifying transistor 101, so that the emitters are connected common. As a result, interference waves or disturbance waves having entered through the ground terminal go through the two separate paths on the signal amplifying transistor 101 side and the output impedance compensation circuit 116 side, and are added up together again at the output terminal 114. Accordingly, even when the output impedance compensation circuit 116 is added, disturbance or interference characteristics such as carrier leak characteristics does not degrade.

Here, in the configuration described above, each of the signal amplifying transistor 101 and the output impedance compensating transistor 102 has been a bipolar transistor. However, each may be composed of a desired transistor such as a MOS field effect transistor. In the circuit configuration of FIG. 1, each of the signal amplifying transistor 101 and the output impedance compensating transistor 102 may be composed of an N-channel MOS transistor.

Further, each transistor has been a single transistor. However, each transistor may be replaced by a series connection of a plurality of transistors or alternatively a series connection of the transistor and other passive elements such as a resistor and an inductor.

As described above, according to this embodiment, the circuit scarcely suffers disturbance or interference such as carrier leak from the other circuit blocks. Further, in a state that a change in the output impedance is suppressed that could be caused in association with a change in the gain, further influence of the disturbance or interference is avoided.

Further, when the gain control signal for the signal amplifying transistor 101 is changed in a direction of increasing the gain of the signal amplifying transistor 101, that is, when the signal is changed in a direction of reducing the output resistance of the signal amplifying transistor 101 viewed from the collector side, the output impedance compensating transistor 102 is controlled in a shut-off direction in correspondence to the gain control signal, so that the resistance realized by the variable resistor function is controlled in an increasing direction. On the contrary, when the signal is changed in a direction of reducing the gain of the signal amplifying transistor 101, that is, when the signal is changed in a direction of increasing the output resistance viewed from the collector side, the resistance realized by the variable resistor function is controlled in a decreasing direction. By virtue of this, a change in the output impedance is suppressed that could be caused in association with a change in the gain.

Further, when the signal amplifying transistor 101 is connected to the separate dedicated grounding pad 110 to which the other circuit blocks are not connected, the circuit scarcely suffers disturbance or interference such as carrier leak from the other circuit blocks. Then, when the newly added output impedance compensating transistor 102 having a variable resistor function is connected to this separate dedicated grounding pad 110, further disturbance or interference is avoided.

Further, when the output impedance compensation circuit 116 controlled by the gain control signal is implemented by the output impedance compensating transistor 102 having a variable resistor function or alternatively by the output impedance compensating transistor 102 and the resistor 103, the output impedance compensation circuit 116 can also be fabricated on the same semiconductor substrate. This realizes built-in of a variable gain amplifier into a high frequency wireless circuit apparatus, which has been difficult in the prior art because of degradation in the disturbance or interference characteristics such as carrier leak characteristics.

Here, the supply voltage applying terminal 109 and the load element 107 may be provided outside the integrated circuit. That is, the load element 107 may be implemented as an external component to the integrated circuit (except for the load element) constituting the variable gain amplifier 122.

### Second Embodiment

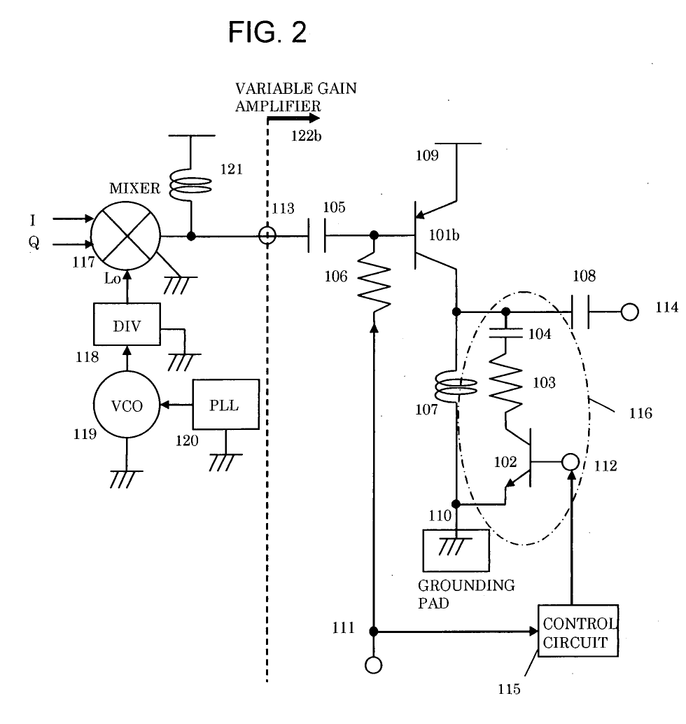

An integrated circuit according to a second embodiment of the present invention is described below with reference to FIG. 2. The differences between the variable gain amplifiers 122b and 122 respectively shown in FIG. 2 and FIG. 1 are that the NPN type signal amplifying transistor 101 (FIG. 1) is changed into a PNP type signal amplifying transistor 101b (FIG. 2) and that the order of connection of the signal amplifying transistor 101b and the load element 107 are reversed. Further difference is whether the output impedance compensation circuit 116 is connected in parallel to the signal amplifying transistor 101 (FIG. 1) or in parallel to the load element 107 (FIG. 2).

The variable gain amplifier 122b of the present invention amplifies at a variable gain the RF signal outputted from the mixer 117. Specifically, in the variable gain amplifier 122b, the high frequency signal inputted through an input terminal 113 is amplified by the signal amplifying transistor (a signal amplifying element) 101b and then outputted through an output terminal 114. At that time, the gain of the signal amplifying transistor 101b can be controlled with a gain control signal provided through the gain control terminal 111.

Further, in this variable gain amplifier 122b, an output impedance compensation circuit (an active circuit) 116 is added to the collector serving as the output terminal of the signal amplifying transistor 101b. The output impedance compensation circuit 116 comprises an output impedance compensating transistor 102, an output impedance compensating resistor 103, and a bypass capacitor 104, and compensates fluctuation of the output impedance of the signal amplifying transistor 101b viewed from the output terminal (the collector) side.

Here, the ground terminal of the load element 107 of the signal amplifying transistor 101b and the ground terminal of the output impedance compensation circuit 116 are connected to a separate dedicated grounding pad 110 to which the ground terminals of the other circuit blocks are not connected.

Here, it is sufficient that the ground terminals of other circuit blocks that could cause disturbance or interference to the signal amplifying transistor 101b are solely not connected to the above-mentioned grounding pad 110. That is, one or more of the other circuit blocks that scarcely affect the characteristics of the signal amplifying transistor 101b may be connected to the grounding pad 110.

In other words, the term “dedicated” used in the present specification indicates that it is sufficient that the ground terminals of other circuit blocks that could cause disturbance or interference to the signal amplifying transistor 101b are solely not connected to the above-mentioned grounding pad 110. Thus, the ground terminals of one or more of the other circuit blocks that scarcely affect the characteristics of the signal amplifying transistor 101b may be connected to the grounding pad 110.

The circuit connection of the variable gain amplifier 122b is described below in detail.

First, the signal amplifying transistor 101b is preferably composed, for example, of a PNP type bipolar transistor. The emitter of the signal amplifying transistor 101b is connected to the supply voltage applying terminal 109. Its base is connected through a bias applying resistor 106 to the gain control terminal 111 and further connected through an input coupling capacitor 105 to the input terminal 113 of the variable gain amplifier. Its collector is connected to a dedicated grounding pad 110 via a load element 107 composed of a choke coil or a resistor, and further connected through an output coupling capacitor 108 to the output terminal 114 of the variable gain amplifier.

Further, the output impedance compensating transistor 102 is preferably composed, for example, of an NPN type bipolar transistor. The collector of the output impedance compensating transistor 102 is connected to the collector of the signal amplifying transistor 101b via an output impedance compensating resistor 103 and a bypass capacitor 104 or alternatively via the bypass capacitor 104 only. Its emitter is connected to the dedicated grounding pad 110. Its base 112 is connected to a control circuit 115 for the output impedance compensating transistor 102. The control circuit 115 is a circuit for generating a control signal for the output impedance compensating transistor 102 on the basis of the gain control signal provided through the gain control terminal 111.

Here, in the configuration described above, each of the signal amplifying transistor 101b and the output impedance compensating transistor 102 has been a bipolar transistor. However, each may be composed of a desired transistor such as a MOS field effect transistor. In the circuit configuration of FIG. 2, the signal amplifying transistor 101b may be composed of a P-channel MOS transistor, while the output impedance compensating transistor 102 may be composed of an N-channel MOS transistor.

Further, each transistor has been a single transistor. However, each transistor may be replaced by a series connection of a plurality of transistors or alternatively a series connection of the transistor and other passive elements such as a resistor and an inductor.

The other points of configuration and operation effects are the same as those of the first embodiment.

### Third Embodiment

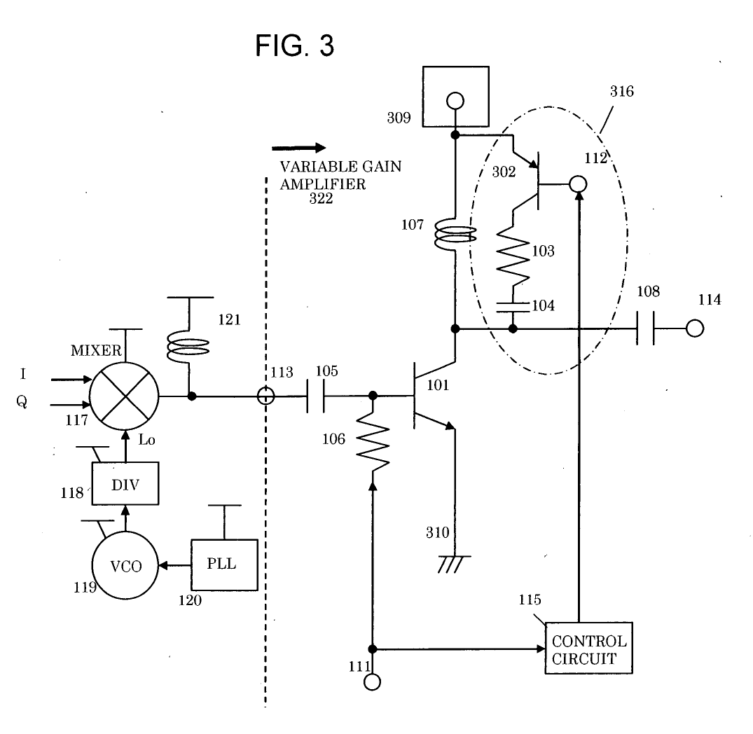

An integrated circuit according to a third embodiment of the present invention is described below with reference to FIG. 3. The difference between the variable gain amplifiers of FIG. 3 and FIG. 1 is whether the output impedance compensation circuit 116 is connected between the collector of the signal amplifying transistor 101 and the ground terminal (FIG. 1) or an output impedance compensation circuit (an active circuit) 316 is connected between the collector of the signal amplifying transistor 101 and a supply voltage applying terminal 309 (FIG. 3). Further difference is whether the output impedance compensation circuit 116 is connected in parallel to the signal amplifying transistor 101 (FIG. 1) or the output impedance compensation circuit 316 is connected in parallel to the load element 107 (FIG. 3).

In the present invention, as shown in FIG. 3, a circuit apparatus is assumed in which a plurality of circuits are constructed on the same semiconductor substrate, like a wireless circuit system (block) where a mixer 117 for performing frequency conversion, a local oscillator 119, and a variable gain amplifier 322, and the like are constructed on a single chip.

In this circuit apparatus, the output signal frequency of the local oscillator 119 is controlled by a frequency synthesizer (a PLL circuit) 120. The output signal of the local oscillator 119 is divided by a frequency divider 118, so that a local oscillation signal Lo is obtained. This local oscillation signal Lo and quadrature modulation signals I and Q (baseband signals) are inputted to the mixer 117, so that an RF signal is outputted from the mixer 117. Here, the output terminal of the mixer 117 is connected through a choke coil 121 to a power supply. This point is the same as that of FIG. 1.

The variable gain amplifier 322 of the present invention amplifies at a variable gain the RF signal outputted from the mixer 117. Specifically, in the variable gain amplifier 322, the high frequency signal inputted through an input terminal 113 is amplified by the signal amplifying transistor 101 and then outputted through an output terminal 114. At that time, the gain of the signal amplifying transistor 101 can be controlled with a gain control signal provided through the gain control terminal 111.

Further, in this variable gain amplifier 322, an output impedance compensation circuit 316 is added to the collector serving as the output terminal of the signal amplifying transistor 101. The output impedance compensation circuit 316 comprises an output impedance compensating transistor 302, an output impedance compensating resistor 103, and a bypass capacitor 104, and compensates fluctuation of the output impedance of the signal amplifying transistor 101 viewed from the output terminal (the collector) side.

Here, the source voltage terminal of the load element 107 (which is composed of a choke coil or a resistor) of the signal amplifying transistor 101 and the source voltage terminal of the output impedance compensation circuit 316 are connected to a separate dedicated supply voltage applying pad 309 to which the source voltage terminals of the other circuit blocks are not connected.

Here, it is sufficient that the supply voltage terminals of other circuit blocks that could cause disturbance or interference to the signal amplifying transistor 101 are solely not connected to the above-mentioned supply voltage applying pad 309. That is, one or more of the other circuit blocks that scarcely affect the characteristics of the signal amplifying transistor 101 may be connected to the supply voltage applying pad 309.

In other words, the term “dedicated” used in the present specification indicates that it is sufficient that the supply voltage terminals of other circuit blocks that could cause disturbance or interference to the signal amplifying transistor 101 are solely not connected to the above-mentioned supply voltage applying pad 309. Thus, the supply voltage terminals of one or more of the other circuit blocks that scarcely affect the characteristics of the signal amplifying transistor 101 may be connected to the supply voltage applying pad 309.

With attention being focused on the difference from FIG. 1, the circuit connection of the variable gain amplifier 322 is described below in detail.

The emitter of the signal amplifying transistor 101 is connected to a ground terminal 310. However, in the third embodiment, the ground terminal 310 is not limited to a dedicated grounding pad to which the ground terminals of the other circuit blocks are not connected.

Further, the output impedance compensating transistor 302 is preferably composed, for example, of a PNP type bipolar transistor. The collector of the output impedance compensating transistor 302 is connected to the collector of the signal amplifying transistor 101 via the output impedance compensating resistor 103 and the bypass capacitor 104 or alternatively via the bypass capacitor 104 only. Its emitter is connected to a dedicated supply voltage applying pad 309. Its base 112 is connected to a control circuit 115 for the output impedance compensating transistor 302.

In the present invention, the output impedance compensating transistor 302 is controlled simultaneously in response to the gain control signal provided through the gain control terminal 111 so that output impedance fluctuation is compensated. As a result, a variable gain amplifier is realized that has low output impedance fluctuation. The principles of its operation are described below.

When the gain of the signal amplifying transistor 101 is increased, the output impedance of the signal amplifying transistor 101 viewed from the collector side decreases. At that time, the output impedance compensating transistor 302 is brought into an OFF state so that the impedance viewed from the collector side is increased. As a result, the output impedance of the signal amplifying transistor 101 is mainly seen from the output terminal 114. Further, when the gain of the signal amplifying transistor 101 is reduced, the output impedance of the signal amplifying transistor 101 viewed from the collector side increases. At that time, the output impedance compensating transistor 302 is brought into an ON state so that the impedance viewed from the collector side is reduced. As a result, the impedance of the part of the output impedance compensation circuit 316 is seen from the output terminal 114.

As such, when the output impedance compensating resistor 103 and the output resistance of the output impedance compensating transistor 302 are adjusted synchronously, a variable gain amplifier is realized that has low output impedance fluctuation regardless of a change in the gain.

Here, adjustment of the resistance is described below in detail. The value of the output impedance compensating resistor 103 is adjusted in such a manner that the value of the output impedance of the signal amplifying transistor 101 viewed from the collector side should be the same when the gain of the signal amplifying transistor 101 is high (when the impedance of the signal amplifying transistor 101 is mainly seen) and when the gain of the signal amplifying transistor 101 is low (when the impedance of the output impedance compensation circuit 316 is mainly seen). During actual operation, the value of the output impedance compensating resistor 103 is fixed, while the output resistance of the output impedance compensating transistor 302 is a variable resistance.

Further, since a PNP type bipolar transistor is employed as the output impedance compensating transistor 302, in addition that ON and OFF states are realized, the impedance can be changed linearly in accordance with the change in the gain. Thus, impedance fluctuation of the signal amplifying transistor 101 can always be compensated.

In the variable gain amplifier 322 of the present invention, the supply voltage applying pad 309 dedicated to the load element 107 of the signal amplifying transistor 101 is provided so that disturbance or interference from the other circuit blocks is reduced.

Further, in the present invention, the supply voltage applying terminal of the output impedance compensation circuit 316 is also connected to the same supply voltage applying pad 309 as that for the load element 107 of the signal amplifying transistor 101. As a result, interference waves or disturbance waves having entered through the supply voltage applying pad 309 go through the two separate paths on the load element 107 side and the output impedance compensation circuit 316 side, and are added up together again at the output terminal 114. Accordingly, even when the output impedance compensation circuit 316 is added, disturbance or interference characteristics such as carrier leak characteristics does not degrade.

Here, in the configuration described above, each of the signal amplifying transistor 101 and the output impedance compensating transistor 302 has been a bipolar transistor. However, each may be composed of a desired transistor such as a MOS field effect transistor. In the circuit configuration of FIG. 3, each of the signal amplifying transistor 101 and the output impedance compensating transistor 302 may be composed of a P-channel MOS transistor.

Further, each transistor has been a single transistor. However, each transistor may be replaced by a series connection of a plurality of transistors or alternatively a series connection of the transistor and other passive elements such as a resistor and an inductor.

As described above, according to this embodiment, the circuit scarcely suffers disturbance or interference such as carrier leak from the other circuit blocks. Further, in a state that a change in the output impedance is suppressed that could be caused in association with a change in the gain, further influence of the disturbance or interference is avoided.

Further, when the gain control signal for the signal amplifying transistor 101 is changed in a direction of increasing the gain of the signal amplifying transistor 101, that is, when the signal is changed in a direction of reducing the output resistance of the signal amplifying transistor 101 viewed from the collector side, the output impedance compensating transistor 302 is controlled in a shut-off direction in correspondence to the gain control signal, so that the resistance realized by the variable resistor function is controlled in an increasing direction. On the contrary, when the signal is changed in a direction of reducing the gain of the signal amplifying transistor 101, that is, when the signal is changed in a direction of increasing the output resistance viewed from the collector side, the resistance realized by the variable resistor function is controlled in a decreasing direction. By virtue of this, a change in the output impedance is suppressed that could be caused in association with a change in the gain.

Further, when the load element 107 is connected to the separate dedicated supply voltage applying pad 309 to which the other circuit blocks are not connected, the circuit scarcely suffers disturbance or interference such as carrier leak from the other circuit blocks. Then, when the newly added output impedance compensating transistor 302 having a variable resistor function is connected to this separate supply voltage applying pad 309, further disturbance or interference is avoided.

Further, when the output impedance compensation circuit 316 controlled by the gain control signal is implemented by the output impedance compensating transistor 302 having a variable resistor function or alternatively by the output impedance compensating transistor 302 and the resistor 103, the output impedance compensation circuit 316 can also be fabricated on the same semiconductor substrate. This realizes built-in of a variable gain amplifier into a high frequency wireless circuit apparatus, which has been difficult in the prior art because of degradation in the disturbance or interference characteristics such as carrier leak characteristics.

### Fourth Embodiment

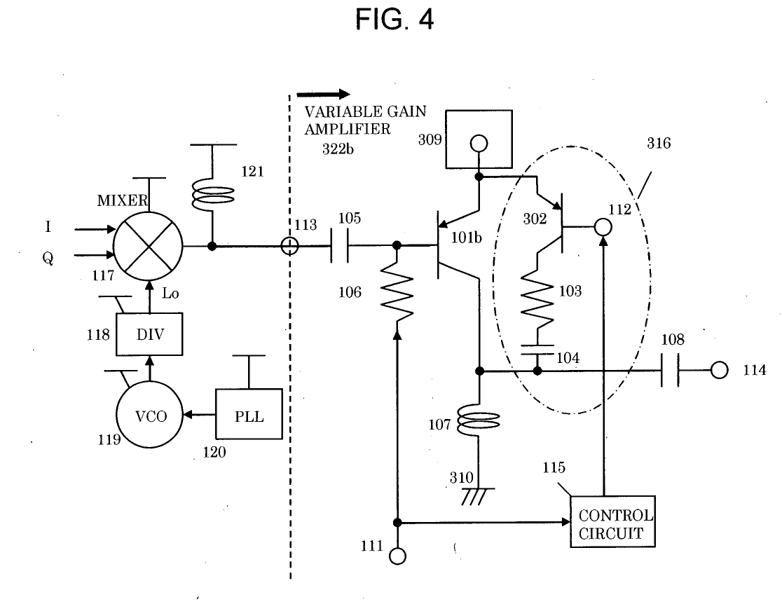

An integrated circuit according to a fourth embodiment of the present invention is described below with reference to FIG. 4. The differences between the variable gain amplifiers 322b and 322 respectively shown in FIG. 4 and FIG. 3 are that the NPN type signal amplifying transistor 101 (FIG. 3) is changed into a PNP type signal amplifying transistor 101b (FIG. 4) and that the order of connection of the signal amplifying transistor 101b and the load element 107 are reversed. Further difference is whether the output impedance compensation circuit 316 is connected in parallel to the load element 107 (FIG. 3) or the output impedance compensation circuit 316 is connected in parallel to the signal amplifying transistor 101b (FIG. 4).

The variable gain amplifier 322b of the present invention amplifies at a variable gain the RF signal outputted from the mixer 117. Specifically, in the variable gain amplifier 322b, the high frequency signal inputted through an input terminal 113 is amplified by the signal amplifying transistor 101b and then outputted through an output terminal 114. At that time, the gain of the signal amplifying transistor 101b can be controlled with a gain control signal provided through the gain control terminal 111.

Further, in this variable gain amplifier 322b, an output impedance compensation circuit 316 is added to the collector serving as the output terminal of the signal amplifying transistor 101b. The output impedance compensation circuit 316 comprises an output impedance compensating transistor 302, an output impedance compensating resistor 103, and a bypass capacitor 104, and compensates fluctuation of the output impedance of the signal amplifying transistor 101b viewed from the output terminal (the collector) side.

Here, the emitter terminal of the signal amplifying transistor 101b and the supply voltage applying terminal of the output impedance compensation circuit 316 are connected to a separate dedicated supply voltage applying pad 309 to which the supply voltage terminals of the other circuit blocks are not connected.

Here, it is sufficient that the supply voltage terminals of other circuit blocks that could cause disturbance or interference to the signal amplifying transistor 101 bare solely not connected to the above-mentioned supply voltage applying pad 309. That is, one or more of the other circuit blocks that scarcely affect the characteristics of the signal amplifying transistor 101b may be connected to the supply voltage applying pad 309.

In other words, the term “dedicated” used in the present specification indicates that it is sufficient that the supply voltage terminals of other circuit blocks that could cause disturbance or interference to the signal amplifying transistor 101b are solely not connected to the above-mentioned supply voltage applying pad 309. Thus, the supply voltage terminals of one or more of the other circuit blocks that scarcely affect the characteristics of the signal amplifying transistor 101b may be connected to the supply voltage applying pad 309.

The circuit connection of the variable gain amplifier 322b is described below in detail.

First, the signal amplifying transistor 101b is preferably composed, for example, of a PNP type bipolar transistor. The emitter of the signal amplifying transistor 101b is connected to the dedicated supply voltage applying pad 309 to which the supply voltage applying terminals of the other circuit blocks are not connected. Its base is connected through a bias applying resistor 106 to the gain control terminal 111 and further connected through an input coupling capacitor 105 to the input terminal 113 of the variable gain amplifier. Its collector is connected to a ground terminal 310 via a load element 107 composed of a choke coil or a resistor, and further connected through an output coupling capacitor 108 to the output terminal 114 of the variable gain amplifier.

Further, the output impedance compensating transistor 302 is preferably composed, for example, of a PNP type bipolar transistor. The collector of the output impedance compensating transistor 302 is connected to the collector of the signal amplifying transistor 101b via the output impedance compensating resistor 103 and the bypass capacitor 104 or alternatively via the bypass capacitor 104 only. Its emitter is connected to a dedicated supply voltage applying pad 309. Its base 112 is connected to a control circuit 115 for the output impedance compensating transistor 302.

Here, in the configuration described above, each of the signal amplifying transistor 101b and the output impedance compensating transistor 302 has been a bipolar transistor. However, each may be composed of a desired transistor such as a MOS field effect transistor. In the circuit configuration of FIG. 4, each of the signal amplifying transistor 101b and the output impedance compensating transistor 302 may be composed of a P-channel MOS transistor.

Further, each transistor has been a single transistor. However, each transistor may be replaced by a series connection of a plurality of transistors or alternatively a series connection of the transistor and other passive elements such as a resistor and an inductor.

The other points of configuration and operation effects are the same as those of the first embodiment.

Here, the ground terminal 310 and the load element 107 may be provided outside the integrated circuit. That is, the load element 107 may be implemented as an external component to the integrated circuit (except for the load element) constituting the variable gain amplifier 322b.

### Fifth Embodiment

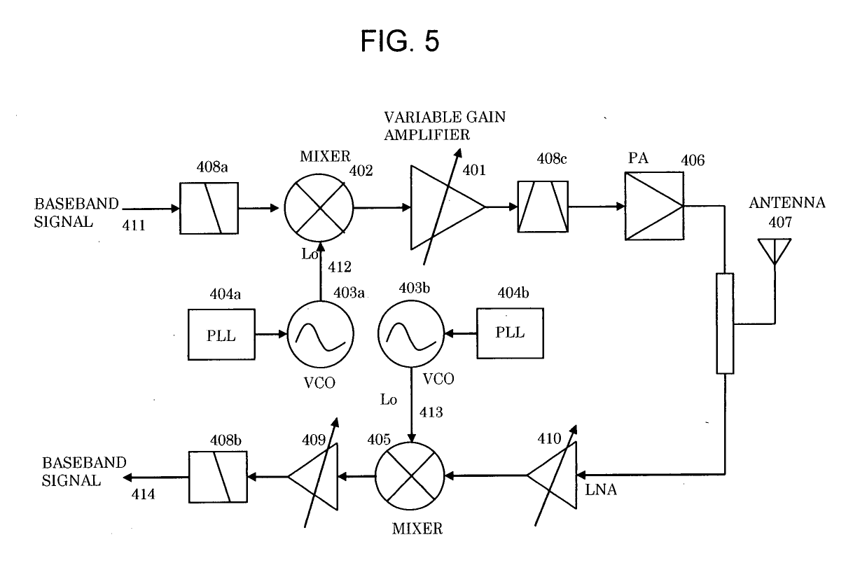

An integrated circuit according to a fifth embodiment of the present invention is described below with reference to FIG. 5.

FIG. 5 is a block diagram showing an example of a high frequency wireless circuit system (apparatus) employing the variable gain amplifier 122 of FIG. 1, the variable gain amplifier 122b of FIG. 2, the variable gain amplifier 322 of FIG. 3, or alternatively the variable gain amplifier 322b of FIG. 4. The circuit configuration and the principles of operation are described below.

As shown in FIG. 5, in the high frequency wireless circuit system, a local oscillation signal 412 of a local oscillator 403a controlled by a frequency synthesizer 404a and a signal obtained from a baseband signal 411 having passed through a low pass filter 408a are multiplied to each other by a mixer 402. Then, the obtained signal is amplified by a variable gain amplifier 401, then goes through a band pass filter 408c, then is amplified further by a high frequency amplifier 406, and then is transmitted through an antenna 407.

Further, a signal received through the antenna 407 is amplified by a low noise amplifier 410, and then multiplied by a mixer 405 to a local oscillation signal 413 of a local oscillator 403b controlled by a frequency synthesizer 404b. The obtained signal then goes through an amplifier 409 and a low pass filter 408b so that a baseband signal 414 is generated.

The above-mentioned variable gain amplifier 401 is composed of the variable gain amplifier 122 of FIG. 1, the variable gain amplifier 122b of FIG. 2, the variable gain amplifier 322 of FIG. 3, or alternatively the variable gain amplifier 322b of FIG. 4.

When the present invention is applied to the variable gain amplifier 401 of the high frequency wireless circuit system of FIG. 5, even when the system is built on the same semiconductor substrate, such a system is achieved that has satisfactory interference or disturbance characteristics such as carrier leak characteristics and that has no matching problem between the circuit blocks regardless of a change in the gain and hence has satisfactory pass characteristics.

Here, the example of the configuration of a high frequency wireless circuit system is not limited to the above-mentioned one. That is, any wireless circuit system may be employed as long as the system comprises: a wireless transmission apparatus provided with at least one variable gain amplifier, at least one local oscillator, and at least one mixer; at least one wireless receiving apparatus; and an antenna connected to the wireless transmission apparatus and the wireless receiving apparatus and capable of transmitting and receiving a signal of at least one radio frequency.

According to this embodiment, the same effect as that of the above-mentioned embodiments is obtained.

### INDUSTRIAL APPLICABILITY

The present invention is useful in amplification of a high frequency signal in wireless communication devices of various kinds.

1. A variable gain amplifier comprising:
a signal amplifying element provided with a ground terminal and amplifying a high frequency signal at a gain corresponding to a gain control signal;
an output impedance compensation circuit provided with a ground terminal and controlled in accordance with said gain control signal so as to compensate fluctuation of an output impedance of said signal amplifying element viewed from the output terminal side; and
a grounding pad connected common to the ground terminal of said signal amplifying element and the ground terminal of said output impedance compensation circuit.

2. A variable gain amplifier comprising:
a signal amplifying element for amplifying a high frequency signal at a gain corresponding to a gain control signal;
a load element provided with a ground terminal and connected to said signal amplifying element;
an output impedance compensation circuit provided with a ground terminal and controlled in accordance with said gain control signal so as to compensate fluctuation of an output impedance of said signal amplifying element viewed from the output terminal side; and
a grounding pad connected common to the ground terminal of said load element and the ground terminal of said output impedance compensation circuit.

3. A variable gain amplifier according to claim 1, formed together with other circuit blocks on the same semiconductor substrate.

4. A variable gain amplifier according to claim 2, formed together with other circuit blocks on the same semiconductor substrate.

5. A variable gain amplifier according to claim 1, wherein said output impedance compensation circuit has a variable resistor function of changing a resistance between the own ground terminal and output terminal, while the output terminal of said output impedance compensation circuit is connected to the output terminal of said signal amplifying element, and wherein
said output impedance compensation circuit is controlled in such a manner that when said gain control signal varies in a direction of increasing the gain of said signal amplifying element, the resistance realized by said variable resistor function should increase, and that when said gain control signal varies in a direction of decreasing the gain of said signal amplifying element, the resistance realized by said variable resistor function should decrease.

6. A variable gain amplifier according to claim 2, wherein said output impedance compensation circuit has a variable resistor function of changing a resistance between the own ground terminal and output terminal, while the output terminal of said output impedance compensation circuit is connected to the output terminal of said signal amplifying element, and wherein
said output impedance compensation circuit is controlled in such a manner that when said gain control signal varies in a direction of increasing the gain of said signal amplifying element, the resistance realized by said variable resistor function should increase, and that when said gain control signal varies in a direction of decreasing the gain of said signal amplifying element, the resistance realized by said variable resistor function should decrease.

7. A variable gain amplifier according to claim 5, wherein the variable resistor function in said output impedance compensation circuit is implemented by a bipolar transistor and a resistor.

8. A variable gain amplifier according to claim 6, wherein the variable resistor function in said output impedance compensation circuit is implemented by a bipolar transistor and a resistor.

9. A variable gain amplifier according to claim 5, wherein the variable resistor function in said output impedance compensation circuit is implemented by a bipolar transistor.

10. A variable gain amplifier according to claim 6, wherein the variable resistor function in said output impedance compensation circuit is implemented by a bipolar transistor.

11. A variable gain amplifier according to claim 5, wherein the variable resistor function in said output impedance compensation circuit is implemented by a field effect transistor.

12. A variable gain amplifier according to claim 6, wherein the variable resistor function in said output impedance compensation circuit is implemented by a field effect transistor.

13. A variable gain amplifier comprising:
a signal amplifying element provided with a supply voltage terminal and amplifying a high frequency signal at a gain corresponding to a gain control signal;
an output impedance compensation circuit provided with a supply voltage terminal and controlled in accordance with said gain control signal so as to compensate fluctuation of an output impedance of said signal amplifying element viewed from the output terminal side; and
a supply voltage applying pad connected common to the supply voltage terminal of said signal amplifying element and the supply voltage terminal of said output impedance compensation circuit.

14. A variable gain amplifier comprising:
a signal amplifying element for amplifying a high frequency signal at a gain corresponding to a gain control signal;
a load element provided with a supply voltage terminal and connected to said signal amplifying element;
an output impedance compensation circuit provided with a supply voltage terminal and controlled in accordance with said gain control signal so as to compensate fluctuation of an output impedance of said signal amplifying element viewed from the output terminal side; and
a supply voltage applying pad connected common to the supply voltage terminal of said load element and the supply voltage terminal of said output impedance compensation circuit.

15. A variable gain amplifier according to claim 13, formed together with other circuit blocks on the same semiconductor substrate.

16. A variable gain amplifier according to claim 14, formed together with other circuit blocks on the same semiconductor substrate.

17. A variable gain amplifier according to claim 13, wherein said output impedance compensation circuit has a variable resistor function of changing a resistance between the own supply voltage terminal and output terminal, while the output terminal of said output impedance compensation circuit is connected to the output terminal of said signal amplifying element, and wherein
said output impedance compensation circuit is controlled in such a manner that when said gain control signal varies in a direction of increasing the gain of said signal amplifying element, the resistance realized by said variable resistor function should increase, and that when said gain control signal varies in a direction of decreasing the gain of said signal amplifying element, the resistance realized by said variable resistor function should decrease.

18. A variable gain amplifier according to claim 14, wherein said output impedance compensation circuit hasa variable resistor function of changing a resistance between the own supply voltage terminal and output terminal, while the output terminal of said output impedance compensation circuit is connected to the output terminal of said signal amplifying element, and wherein
said output impedance compensation circuit is controlled in such a manner that when said gain control signal varies in a direction of increasing the gain of said signal amplifying element, the resistance realized by said variable resistor function should increase, and that when said gain control signal varies in a direction of decreasing the gain of said signal amplifying element, the resistance realized by said variable resistor function should decrease.

19. A variable gain amplifier according to claim 17, wherein the variable resistor function in said output impedance compensation circuit is implemented by a bipolar transistor and a resistor.

20. A variable gain amplifier according to claim 18, wherein the variable resistor function in said output impedance compensation circuit is implemented by a bipolar transistor and a resistor.

21. A variable gain amplifier according to claim 17, wherein the variable resistor function in said output impedance compensation circuit is implemented by a bipolar transistor.

22. A variable gain amplifier according to claim 18, wherein the variable resistor function in said output impedance compensation circuit is implemented by a bipolar transistor.

23. A variable gain amplifier according to claim 17, wherein the variable resistor function in said output impedance compensation circuit is implemented by a field effect transistor.

24. A variable gain amplifier according to claim 18, wherein the variable resistor function in said output impedance compensation circuit is implemented by a field effect transistor.

25. A wireless circuit system comprising: a wireless transmission apparatus provided with at least one variable gain amplifier according to claim 1, at least one local oscillator, and at least one mixer; at least one wireless receiving apparatus; and at least one antenna connected to said wireless transmission apparatus and said wireless receiving apparatus and transmitting and receiving a radio frequency signal.

26. A wireless circuit system comprising: a wireless transmission apparatus provided with at least one variable gain amplifier according to claim 2, at least one local oscillator, and at least one mixer; at least one wireless receiving apparatus; and at least one antenna connected to said wireless transmission apparatus and said wireless receiving apparatus and transmitting and receiving a radio frequency signal.

27. A wireless circuit system comprising: a wireless transmission apparatus provided with at least one variable gain amplifier according to claim 13, at least one local oscillator, and at least one mixer; at least one wireless receiving apparatus; and at least one antenna connected to said wireless transmission apparatus and said wireless receiving apparatus and transmitting and receiving a radio frequency signal.

28. A wireless circuit system comprising: a wireless transmission apparatus provided with at least one variable gain amplifier according to claim 14, at least one local oscillator, and at least one mixer; at least one wireless receiving apparatus; and at least one antenna connected to said wireless transmission apparatus and said wireless receiving apparatus and transmitting and receiving a radio frequency signal.
